(19) United States
(12) Patent Application Publication
(10) Pub. No.: US 2025/0366217 A1
(43) Pub. Date: Nov. 27, 2025

(54) ESD POWER CLAMP

(71) Applicant: Micron Technology, Inc., Boise, ID (US)

(72) Inventors: Kishan Chanumolu, Bengaluru (IN); Radhakrishnan Sithanandam, Hyderabad (IN)

(21) Appl. No.: 19/206,437

(22) Filed: May 13, 2025

Related U.S. Application Data
(60) Provisional application No. 63/650,078, filed on May 21, 2024.

(51) Int. Cl. H10D 89/60

(52) U.S. Cl. CPC H10D 89/819

(57) ABSTRACT

The present disclosure includes apparatuses and methods related to split placement of a pre-driver to provide uniform turn-on of a power clamp in shunting an electrostatic discharge (ESD) current. An example method includes detecting ESD event and in response to the detected ESD event, the method includes splitting a pre-driver output to send triggering signals to multiple big-Field-Effect Transistor (bigFET) gate fingers via different feeding points on a gate finger manifold that interconnects the bigFET gate fingers. The method further includes shunting an ESD current using an activated bigFET.

### PRIORITY INFORMATION

This application claims the benefit of U.S. Provisional Application No. 63/650,078, filed on May 21, 2024, the contents of which are incorporated herein by reference.

### TECHNICAL FIELD

The present disclosure relates generally to electronic apparatuses, and more particularly to apparatuses and methods for providing electrostatic discharge (ESD) protection for an integrated circuit (IC) device.

### BACKGROUND

An ESD protection circuit or power clamp is an important component in electronic systems to safeguard integrated circuits (ICs) and other sensitive electronic devices from damage caused by ESD events. The ESD protection circuit may be integrated into an IC chip to provide a low-impedance channel to the ground. For example, all of the input/output (I/O) pads of an IC are generally protected via an ESD network that can include power clamps in the supply pads.

### BRIEF DESCRIPTION OF THE DRAWINGS

FIG. 1 is a block diagram of an integrated circuit (IC) device having a pre-driver with a split circuit layout to generate multiple triggering signals in accordance with a number of embodiments of the present disclosure.

FIG. 2 is a block diagram illustrating a more detailed example of an ESD power clamp having a pre-driver with a split circuit physical layout placement for activating a bigFET-ESD power clamp in accordance with a number of embodiments of the present disclosure.

FIG. 3 illustrates a method for activating a bigFET using a pre-driver with a split circuit physical layout placement in accordance with a number of embodiments of the present disclosure.

### DETAILED DESCRIPTION

The present disclosure includes apparatuses and methods related to providing ESD protection for an IC device and particularly, to IC devices that support high-speed and/or high/low-power applications. For example, electrical circuits that operate at high power and frequency may require corresponding IC devices having Metal-Oxide-Semiconductor Field-Effect Transistor (MOSFET) type of transistors that are capable of reliably operating at such high frequency while still being capable of handling the high-power loads. In this example, an ESD power clamp may be integrated into the IC device to provide circuit protection in case of an ESD event (e.g., strike). The ESD power clamp, for example, may use a bigFET to implement an ESD power clamp and protect the IC device from damage. A bigFET includes, for example, an array of MOSFETs that are arranged in rows and columns having corresponding parallel-connected segments (referred to herein as bigFET gate fingers) to increase its current-carrying capacity and reduce on-resistance. The bigFET (interchangeably referred to herein as the array of MOSFETs) can comprise n-channel MOSFET (NMOS) transistors or p-channel MOSFET (PMOS) transistors having multiple fingers and a large channel width to enhance the high-current capability and to lower the clamping voltage.

To support high voltage discharges, the size of the bigFET may be further increased. For example, the number of parallel connected MOSFETs that are arranged in rows and columns on the transistor semiconductor substrate can be increased. By increasing the size of the MOSFETs and by extension, the number of parallel-connected bigFET gate fingers, the effective width of the bigFET is also increased. The increased number of bigFET gate fingers collectively contributes to the current-carrying capacity of the bigFET. However, a downside of increasing the number and thus, the effective width of the bigFET gate fingers will result in variations of resistances along the transistor semiconductor substrate. This variation in resistance generates signal phase variations and thus, a delay in activation of the array of MOSFETs along a portion of the transistor semiconductor substrate that has a high resistance. The delay in activation or non-uniform turn-on of the bigFET will not effectively facilitate the clamping down of the electrical circuit which can cause damage to the IC device.

Aspects of the present disclosure address the above and other deficiencies by having a pre-driver with a split circuit physical layout placement to provide the uniform on-time activation of the bigFET (or array of MOSFETs) during the ESD event. For example, embodiments can leverage the split physical circuit layout placement of the pre-driver to generate separate triggering signals to different sets of bigFET gate fingers. The set of bigFET gate fingers may be formed from a grouping of parallel connected MOSFETs. In this example, the bigFET gate fingers receive the triggering signals via different feeding points to compensate for the different net resistances across the bigFET. The different feeding points include, for example, opposite ends or edges of an elongated gate finger manifold that interconnects the bigFET gate fingers. The elongated gate finger manifold may include a conductive substrate line that physically interconnects the different bigFET gate fingers that are formed from the parallel connected MOSFETs. Accordingly, embodiments can result in shifting of the higher net resistance to a central portion of the bigFET (corresponding to a center portion of the gate finger manifold) leading to improved performance.

As used herein, the singular forms “a”, “an”, and “the” include singular and plural referents unless the content clearly dictates otherwise. Furthermore, the word “may” is used throughout this application in a permissive sense (i.e., having the potential to, being able to), not in a mandatory sense (i.e., must). The term “include,” and derivations thereof, mean “including, but not limited to.” The term “coupled” means directly or indirectly connected.

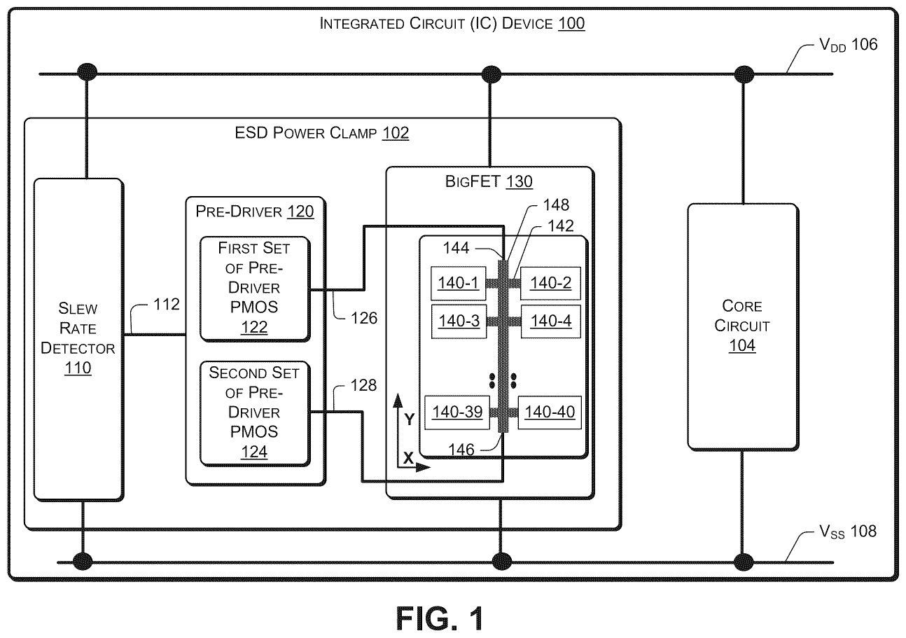

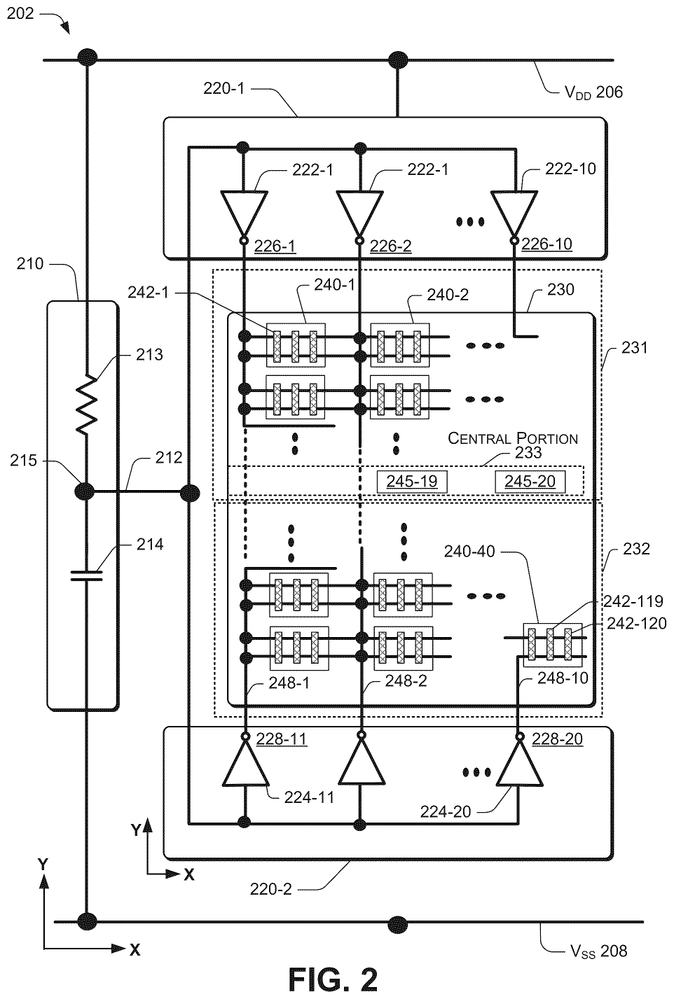

The figures herein follow a numbering convention in which the first digit or digits correspond to the drawing figure number and the remaining digits identify an element or component in the drawing. Similar elements or components between different figures may be identified by the use of similar digits. For example, 110 may reference element “10” in FIG. 1, and a similar element may be referenced as 210 in FIG. 2. Analogous elements within a Figure may be referenced with a hyphen and extra numeral or letter. As will be appreciated, elements shown in the various embodiments herein can be added, exchanged, and/or eliminated so as to provide a number of additional embodiments of the present disclosure. In addition, as will be appreciated, the proportion and the relative scale of the elements provided in the figures are intended to illustrate certain embodiments of the present invention and should not be taken in a limiting sense.

FIG. 1 is a block diagram of an IC device 100 having a pre-driver 120 with a split circuit layout placement to provide a uniform turn-on of a bigFET 130 in accordance with a number of embodiments of the present disclosure. In an embodiment, the bigFET 130 is implemented by an array of MOSFETs 140 having multiple parallel-connected segments (e.g., bigFET gate fingers 142) to enhance the bigFET current-carrying capability. The array of MOSFETs 140 can be arranged in rows and columns and further connected in parallel to increase the effective width (or current-carrying capacity) of the bigFET 130. In this embodiment, the bigFET 130 is configured to implement the voltage clamping in an ESD power clamp 102, which includes an apparatus or system that protects the IC device 100. The bigFET 130 includes the bigFET gate fingers 142 that can be parallel connected, for example, by a gate finger manifold 148 which is a semiconductor structure or physical conductive line substrate in the bigFET 130. The number of bigFET gate fingers 142 may depend upon the number of parallel-connected MOSFETs 140 that are grouped in the arrays of MOSFETs 140. For example, a set of 3 parallel connected transistors in MOSFET 140-1 may form three bigFET gate fingers 142. In this example, the three bigFET gate fingers 142 are interconnected in parallel with the other bigFET gate fingers from the other group of MOSFETs through the gate finger manifold 148. Further, the three bigFET gate fingers 142 correspond to an increase in the effective width of the bigFET 130.

In some embodiments, the pre-driver 120 feeds triggering signals to different feeding points (e.g., first feeding point 144 and second feeding point 146) on the gate finger manifold 148 to cancel or at least reduce the delay in the transmission of the triggering signals to respective gates of the array of MOSFETs 140. The delay may be enhanced by the length of the column and/or row arrangement of the MOSFETs, for example. The reduction or cancellation of the delay will provide a uniform turn-on of the MOSFETs 140 and thus, the bigFET 130 in the IC device 100. The IC device 100 can be, for example, a system, apparatus, or a System-on-Chip (SoC); however, embodiments are not limited to a particular type of electronic system.

As shown, the IC device 100 may include the ESD power clamp 102 and a core circuit 104 which are connected to a power supply rail—Vdd 106 and lower-voltage rail Vss 108 (e.g., ground). The ESD power clamp 102 may further include a slew rate detector 110; the pre-driver 120 having a circuit layout that separates a first set of PMOS pre-driver 122 from a second set of PMOS pre-driver 124; and the bigFET 130 that is implemented by the array of MOSFETs 140. The bigFET gate fingers 142 of the MOSFETs 140, for example, may include the interconnected gate electrodes of parallel connected MOSFETs 140-1 to 140-40. For illustrative purposes, the interconnected drain electrodes, source electrodes, and/or biasing voltages of the MOSFETs 140-1 to 140-40 were not shown to simplify the illustration.

FIG. 1 further illustrates an ESD detection signal 112 that is generated by the slew rate detector 110 upon detection of the ESD event; a first triggering signal 126 and a second triggering signal 128 that are respectively generated by the first set of PMOS pre-driver 122 and the second set of PMOS pre-driver 124; and the first feeding point 144 and the second feeding point 146 at opposite ends of the bigFET 130.

As an overview of the operation in FIG. 1, the ESD power clamp 102 detects the ESD event (not shown) using the slew rate detector 110, and then the pre-driver 120 activates the bigFET 130 to shunt the high transient current due to the ESD event. The bigFET 130 is an example protective or clamping circuitry that shunts the high current and thus, limits the excess power that may cause damage to the core circuit 104. The shunting of the high transient current provides protection to the core circuit 104. The pre-driver 120 is not limited to having PMOS transistors but can also be configured to include NMOS transistors. Further, the circuit layout of the pre-driver 120 is not limited to being split into two portions but the pre-driver 120 can be split into more than two portions to support the triggering of the bigFET 130 via the different feeding points on the gate finger manifold 148.

For example, depending on the current capability of the assigned pre-driver 120 to handle a total gate charge to activate a particular group or set of parallel-connected MOSFETs, an additional pre-driver can be added to supply the triggering current at the same or different feeding point on the gate finger manifold 148. In this example, the feeding point provides a smaller resistance to the triggering current to avoid delay in the turning on of the associated MOSFETs 140. In alternative or additional embodiments, a separate gate finger manifold is dedicated to connecting the bigFET gate fingers associated with a particular column (not shown) of MOSFETs. In this embodiment, the triggering current is supplied at the opposite edges of the dedicated gate finger manifold to provide the small resistance to the triggering current that will activate the particular column of MOSFETs.

The IC device 100 can be used in various applications, such as high-power automotive applications, communications applications, industrial applications, medical applications, computer applications, and/or consumer or appliance applications. The IC device 100 can be implemented in a substrate, such as a semiconductor wafer or a printed circuit board (PCB). In an embodiment, the IC device 100 is packaged as a semiconductor IC chip. The IC device 100 may be included in a microcontroller, which can be used for, for example, in vehicle control or communications, identification, wireless communications, and/or lighting control. In some embodiments, the IC device 100 utilizes the ESD power clamp 102 to avoid potential ESD events during the shipping and handling of packaged devices. A human touch, for example, may cause a sudden flow of electricity between objects with different electrostatic potentials.

The core circuit 104 may include a device that is protected by the ESD power clamp 102 in case of an ESD strike or event. The core circuit 104 can include one or more internal circuit components that are susceptible to ESD strikes. Examples of the core circuit 104 include but are not limited to microcontrollers, transceivers, and high-power switching circuits. In an embodiment, the core circuit 104 includes a power supply domain of the IC device 100 which is a specific region or section of the IC device 100 where a particular power supply or voltage level is applied. In multi-functional devices, different sections of the core circuit 104 may require different power supply voltages to optimize performance, power consumption, and overall functionality.

The ESD power clamp 102 may include components to control the spike in current and/or surge in voltages during the ESD event or strike. The ESD power clamp 102 may be configured to include a particular circuit layout to protect the power supply domain of the IC device 100. For example, the ESD power clamp 102 may use the bigFET 130 to shunt the high current during the ESD event and thereby prevent damage in the core circuit 104. In this example, the ESD power clamp 102 may include a circuit layout such as split placement of the pre-driver 120 to provide uniform turn-on of the MOSFETs 140 that implement the bigFET 130.

The ESD power clamp 102 is implemented by a suitable semiconductor device having MOSFETs and corresponding multiple bigFET gate fingers 142 to enhance the bigFET current-carrying capability. In an embodiment, the bigFET gate fingers 142 may include separate feeding points when receiving the first triggering signal 126 and the second triggering signal 128 from the pre-driver 120. The first or second triggering signal may include the amplified, filtered, and/or conditioned ESD detection signal 112. The use of the separate feeding points (first feeding point 144 and second feeding point 146) reduces or cancels the delay in the transmission of the triggering signals and in effect, provides uniform turn-on of the MOSFETs 140 that are associated with the bigFET gate fingers 142. In some embodiments, the first triggering signal 126 may be different from the second triggering signal 128.

The bigFET 130 include the gate fingers 142 of the array of MOSFETs 140 that collectively contribute to increasing the current-carrying capacity of the bigFET 130. The size of the bigFET 130 may be widened in the x-direction and/or y-direction to effectively widen and increase the current-carrying capability of the associated MOSFETs. The effective widening is proportional to the number of parallel connected MOSFET 140 that implement the bigFET 130. By increasing the size of the bigFET 130 in the x-direction and/or y-direction, the bigFET can protect the power supply domain of the IC device 100 from overvoltage during the ESD event by shunting the ESD current from the power supply domain (Vdd 106) to the ground domain (or supply ground). In some embodiments, the channel width of the bigFET gate fingers 142 can be chosen to ensure that the voltage drop across the bigFET 130 during the ESD event does not exceed a predetermined voltage, which is considered harmful to the inner circuit components (e.g., the core circuit 104) of the IC device 100. The predetermined voltage is typically set to be equal to or around the power supply voltage of the IC device 100.

In some embodiments, the number of MOSFET 140 and thus, the number of bigFET gate fingers 142, may be increased to ensure that the voltage drop across the bigFET during the ESD event does not exceed the predetermined voltage. Increasing the size of the MOSFET 140 in the row and/or column direction may correspond to increasing the effective width of the bigFET 130. For example, an increase in the number of rows of the bigFET gate fingers 142 correspondingly increases the physical length of the bigFET and thus, the length of the gate finger manifold 148 in the y-direction. In this regard, the separate feeding points may be utilized to cancel the delay in the transmission of the triggering signals to the bigFET gate fingers 142 from one end of the gate finger manifold 148 which typically occurs when only one feeding point is utilized e.g., only one opposite end or edge of the gate finger manifold 148 is receiving the triggering signal.

As described herein, the first feeding point 144 is located at one end or edge of the bigFET 130 and particularly, at one end or edge of a length the gate finger manifold 148. On the other hand, the second feeding point 146 is located at the other end or edge of the length of the gate finger manifold 148. For a particular number of bigFET gate fingers 142 corresponding to the number of parallel-connected MOSFETs 140, the gate finger manifold 148 includes a conductive semiconductor substrate that extends along the y-direction and parallel interconnects the bigFET gate fingers 142.

The gate finger manifold 148 is a semiconductor structure or physical conductive substrate line in the ESD power clamp 102 that connects the multiple bigFET gate fingers 142. As the number of rows and/or columns of the parallel-connected MOSFETs 140 increases, the physical length (e.g., y-direction) of the gate finger manifold conductive substrate line also increases. The physical bigFET package may therefore place a constraint on the number of bigFET gate fingers 142 to be included in the IC device 100 because of non-uniform signal phase distribution that may occur along the length of the gate finger manifold 148. In this regard, the physical split circuit layout placement of the pre-driver 120 may be leveraged to transmit the triggering signals to the MOSFETs 140 via the different placements of the feeding points in the gate finger manifold 148. Only 40 MOSFETs 140 or groups of MOSFETs 140 are shown; however, additional MOSFETs 140 arranged in rows and/or columns can be implemented. The multiple bigFET gate fingers that can be formed from these rows and/or columns of MOSFETs 140 may be interconnected via the gate finger manifold 148.

In some embodiments, each of the bigFET gate fingers is connected to both sides of the gate finger manifold 148. For example, a particular gate finger is represented by a longitudinal gate substrate having two edges. In this example, one edge of the gate finger is connected to one side (not shown) of the gate finger manifold 148 while the other edge of the gate finger is connected to the other side of the gate finger manifold 148.

The pre-driver 120 includes a circuit that is configured to condition the received ESD detection signal 112 and generate the triggering signals to turn on the bigFET 130. The conditioning of the received ESD detection signal 112 may include amplifying, filtering, etc. of the ESD detected signal from the slew rate detector 110. In an embodiment, the MOSFETs of the pre-driver 120 may be divided or split into at least two portions when driving the MOSFETs 140 via their corresponding bigFET gate fingers 142.

For example, the first set of PMOS pre-driver 122 of the pre-driver 120 generates and sends the generated first triggering signal 126 via the first feeding point 144 while the second set of PMOS pre-driver 124 can generate and send a separate second triggering signal 128 via the second feeding point 146. In this example, the first feeding point 144 and the second feeding point 146 are respectively located at opposite edges or ends of the length (in the y-direction) of the gate finger manifold 148 although the embodiments are not limited to this. By sending the triggering signals via the separate feeding points, the bigFET gate fingers 142 of the corresponding MOSFETs 140 will receive without delay the triggering signals and thereby provide the uniform turn-on of the associated MOSFETs that can shunt the current during the ESD strike. For ease of illustration, a main driver stage is not shown although the pre-driver 120 will typically drive the main driver which can also be configured to generate and send the triggering signals to the different feeding points on the gate finger manifold 148.

The slew rate detector 110 may be configured to detect the ESD event as described herein. In some embodiments, slew rate detector 110 sends the ESD detection signal 112 in response to an IC pad-voltage change that is above a certain slew rate or preconfigured threshold, for example. The slew rate detector 110 and the pre-driver 120 forms a trigger circuit that controls the activation and de-activation of the MOSFETs 140. For example, the slew rate detector 110 can detect a rise in the power supply voltage Vdd 106 of the IC device 100, which is a characteristic of the ESD event. The pre-driver 120 may then receive the ESD detection signal 112 from the slew rate detector 110 and use the received ESD detection signal 112 as a reference for the generating and sending of the triggering signals. In this example, the pre-driver 120 may be only active during the initial detection of the ESD event to trigger the bigFET 130.

FIG. 2 is a block diagram illustrating a more detailed example of an ESD power clamp 202 having a pre-driver 220 with a split circuit layout (pre-driver portions 220-1 and 220-2) for activating a bigFET 230 in accordance with a number of embodiments of the present disclosure. As shown, the ESD power clamp 202, slew rate detector 210, a first set of PMOS pre-driver 222 of the pre-driver portion 220-1, a second set of PMOS pre-driver 224 of the pre-driver portion 220-2, and the bigFET 230 having array of MOSFETs 240 with bigFET gate fingers 242 correspond to the ESD power clamp 102, slew rate detector 110, first set of PMOS pre-driver 122, second set of PMOS pre-driver 124, and the bigFET 130 having array of MOSFETs 140 with bigFET gate fingers 142 in FIG. 1, respectively.

Similarly, the ESD detection signal 212 generated by the slew rate detector 210, first triggering signals 226-1 to 226-10, and the second triggering signals 228-11 to 228-20 correspond to the ESD detection signal 112 generated by the slew rate detector 110, first triggering signals 126, and the second triggering signals 128 of FIG. 1, respectively.

FIG. 2 illustrates the grouped MOSFETs 240-1 to 240-40 including the associated bigFET gate fingers 242 that can be formed from the parallel connected MOSFETs or transistors; however, the interconnected drains, sources, and biasing voltages in the array of MOSFETs 240 were not shown to simplify the illustration. Further, although the embodiments described herein include PMOS pre-drivers and PMOS pre-driver portions to drive NMOS MOSFETs, the embodiments are not so limited. The ESD power clamp can also utilize NMOS pre-driver or NMOS pre-driver portions to drive the array of PMOS MOSFETs.

In an embodiment, each of MOSFETs 240-1 to 240-40 is associated with three bigFET gate fingers 242. For example, the bigFET gate fingers 242-1 to 242-60 can be associated with the parallel-connected MOSFETs 240-1 to 240-20, which receive the first triggering signals 226-1 to 226-10 from the first set of PMOS pre-driver 222-1 to 222-10 of the pre-driver portion 220-1. In another example, the bigFET gate fingers 242-61 to 242-120 can be associated with the parallel-connected MOSFETs 240-21 to 240-40, which receive the second triggering signals 228-11 to 228-20 from the second set of PMOS pre-driver 224-11 to 224-20 of the pre-driver portion 220-2. In these examples, the MOSFETs 240 can be arranged in rows and columns, and further connected in parallel to increase the effective width of the bigFET 240. Further, each pre-driver in the first and second set of PMOS pre-drivers can be configured to generate enough gate charge to drive the associated MOSFETs 240.

For example, the first triggering signal 226-1 from the PMOS pre-driver 222-1 is assigned to supply the gate charge to the bigFET gate fingers 242-1 to 242-6 associated with the MOSFETs 240-1 and 240-2; the second triggering signal 226-2 is used to supply the gate charge to the bigFET gate fingers 242-7 to 242-12 associated with the MOSFETs 240-3 and 240-4, and so on. At the opposite side or edge of the bigFET 230, the eleventh triggering signal 228-11 from the PMOS pre-driver 224-11 is assigned to supply the gate charge to the bigFET gate fingers 242-61 to 242-66 associated with the MOSFETs 240-11 and 240-12; the next triggering signal 226-12 is used to supply the gate charge to the bigFET gate fingers 242-67 to 242-72 associated with the MOSFETs 240-13 and 240-14, and so on. In these examples, the assigned MPS pre-drivers are configured to generate enough gate charge to drive the associated MOSFETs 240. Further, the bigFET gate fingers 242-1 to 242-120 may be connected physically via the gate finger manifold-semiconductor substrate such as gate finger manifolds 248-1 to 248-10, which correspond to the gate finger manifold 148 in FIG. 1.

In some embodiments, the gate finger manifold may be represented individually by each column of the MOSFETs 240 in the bigFET 240. For example, the MOSFETs 240-1 to 240-40 are arranged in 4 rows and 10 columns. In this example, ten separate gate finger manifolds (e.g., gate finger manifolds 248-1 to 248-10) can implement the gate finger manifold 148 in FIG. 1. In other embodiments, and for the same example, only one gate finger manifold 248 may be formed from the 10 columns of MOSFETs 240. In these embodiments, the first set of triggering signals 226-1 to 226-10 are fed at one edge of the length of the gate finger manifold 248 while the second set of triggering signals 228-11 to 228-20 are supplied via the opposite end or edge of the gate finger manifold 248. The opposite edges of the gate finger manifold 248, for example, correspond to the first feeding point 144 and the second feeding point 146 of FIG. 1.

In some embodiments, each of the bigFET gate fingers 242-1 to 242-130 is connected to both sides of the gate finger manifold 248. For example, a particular gate finger is represented by a longitudinal gate substrate having two edges. In this example, one edge of the gate finger is connected to one side of the gate finger manifold 248 while the other edge of the gate finger is connected to the other side of the gate finger manifold 248. The two sides of the gate finger manifold 248 may include upper and lower surfaces, respectively, of the physical conductive substrate line that represents the gate finger manifold.

In some embodiments, the slew-rate detector 210 includes a resistive-capacitive (RC) circuit having a resistor 213 which is connected in series with a capacitor 214 between the Vdd 206 and the Vss 208. The first terminal of resistor 213 is connected to the Vdd 206 while a second terminal of resistor 213 is connected to node 215, which provides the ESD detection signal 212 that indicates the detection of the ESD event. For example, an ESD rise time detection limit for the power supply clamp is 60 ns. That is, a rise time of 60 ns or more indicates a normal operation and the transistor switching circuit remains in an OFF state. However, in a case where the slew rates or rise time is less than 60 ns, then the RC circuit may generate the ESD detection signal 212 that can be used as a reference by the pre-driver 220 in actuating the bigFET 230 that are implemented by the MOSFETs 240 as described herein.

Each of the pre-drivers 220-1 and 220-2 is a circuit that is configured to condition the ESD detection signal 212 and generate the conditioned signal to turn-on the MOSFETs 240-1 to 240-40 once the ESD event is detected by the slew rate detector 210. In an embodiment, the pre-drivers 220-1 and 220-2 (or pre-driver 220) may turn-on the MOSFETs 240-1 to 240-40 by sending the triggering signals to the associated bigFET gate fingers 242-1 to 242-120 which are interconnected by the gate manifold along the length (i.e., y-direction) of the semiconductor substrate, for example. To reduce or cancel the delay in the transmission of the triggering signals, the circuit layout of the pre-driver 220 is subdivided into two parts to support the corresponding MOSFETs 240.

For example, the first set of PMOS pre-driver 222-1 to 222-10 will provide the triggering signals to a first portion 231 of the bigFET 230 while the second set of PMOS pre-driver 224-11 to 224-20 provide the triggering signals to a second portion 232. The first portion 231 includes the MOSFETs 240-1 to 240-20 that are associated with the bigFET gate fingers 242-1 to 242-60 while the second portion 232 can include the MOSFETs 240-21 to 240-40 that are associated with the bigFET gate fingers 242-61 to 242-2120.

By separating the triggering signals for the first portion 231 and the second portion 232, a central portion 233 of the bigFET 230 may experience high resistance and thus, a gate net resistance gradient across the bigFET 230 is normalized from both sides i.e., first portion 232 and second portion 232. The separate triggering signals, as described herein, are fed through different edges or ends of the gate finger manifold to avoid delay in the turning on of the MOSFETs 240 and thus, effectively facilitate the clamping down of the electrical circuit which can cause damage to the IC device.

In some embodiments, each of the transistors in the pre-drivers 220-1 and 220-2 uses a single PMOS transistor to generate a triggering signal for one or more bigFET gate fingers. For example, a first PMOS pre-driver 222-1 may generate a triggering signal 226-1 for the bigFET gate fingers to 242-1 and 242-6, a second PMOS pre-driver 222-2 may generate a triggering signal 226-2 for the bigFET gate fingers to 242-7 and 242-12, and so on. In this example, the triggering signals 226 and the triggering signals 228 are supplied via different feeding points (not shown) of the bigFET 230.

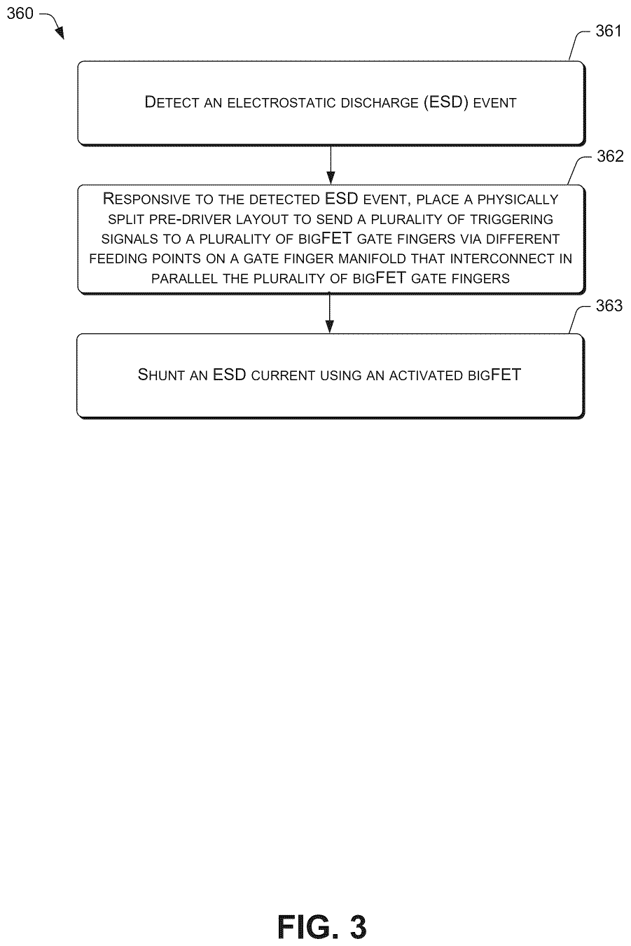

FIG. 3 illustrates a method 360 for activating the ESD power clamp using a pre-driver with a split circuit layout to provide a uniform turn-on of the bigFET in accordance with a number of embodiments of the present disclosure.

The method can be performed by processing logic that can include hardware (e.g., a processing device, circuitry, dedicated logic, programmable logic, microcode, hardware of a device, integrated circuit, etc.), software (e.g., instructions run or executed on a processing device), or a combination thereof. One or more processes can be omitted in various embodiments. Thus, not all processes are required in every embodiment. Other process flows are possible.

At block 361, an ESD event is detected (e.g., via a slew rate detector 110 shown in FIG. 1).

At block 362, in response to the detected ESD event, place a physically split pre-driver layout to send a plurality of triggering signals to a plurality of bigFET gate fingers via different feeding points on a gate finger manifold that interconnects the plurality of bigFET gate fingers. For example, referring to FIG. 2, the split physical circuit layout of the pre-driver 220 may result in the formation of the first set of PMOS pre-driver 222 and the second set of PMOS pre-driver 224. In this example, the first set of PMOS pre-driver 222 can send the generated triggering signals to the first half of the bigFET gate fingers 242 while the second set of PMOS pre-driver 224 may send the generated triggering signals to the other half of the same. The bigFET gate fingers 242 are associated with the array of MOSFETs 240 that are arranged in rows and columns to increase the current-carrying capacity of the ESD power clamp.

In some embodiments, the bigFET gate fingers are interconnected by the gate finger manifold that includes two or more feeding points to receive the triggering signals.

At block 363, an ESD current is shunted using an activated bigFET. For example, and in response to the detection of the ESD event, the array of MOSFETs 240 is activated via the interconnected bigFET gate fingers. By supplying the gate charges from two or more feeding points on the gate finger manifold, the array of MOSFETs may turn on at substantially the same time and without delay.

In some embodiments, a computer system can correspond to a system (e.g., the IC device 100 described with respect to FIG. 1). The computer system may execute a set of instructions to perform the various embodiments of the present disclosure. The computer system, for example, is coupled to, or utilizes a memory sub-system that can be used to perform the operations of control circuitry (e.g., ESD power clamp 102). In alternative embodiments, the computer system can be connected (e.g., networked) to other systems and/or devices in a LAN, an intranet, an extranet, and/or the Internet. The computer system can operate in the capacity of a server or a client machine in client-server network environment, as a peer device in a peer-to-peer (or distributed) network environment, or as a server or a client machine in a cloud computing infrastructure or environment.

In the foregoing Detailed Description, various features are grouped together in a single embodiment for the purpose of streamlining the disclosure. This method of disclosure is not to be interpreted as reflecting an intention that the disclosed embodiments of the present disclosure have to use more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. A method, comprising:
detecting an electrostatic discharge (ESD) event;
responsive to the detected ESD event, sending, via a physically split pre-driver layout, a plurality of triggering signals to a plurality of big-Field-Effect Transistor (bigFET) gate fingers via different feeding points on a bigFET gate finger manifold that interconnect in parallel the bigFET gate fingers; and
shunting an ESD current using an activated bigFET.

2. The method of claim 1, wherein the different feeding points for different triggering signals include a first feeding point at one edge of the bigFET gate finger manifold and a second feeding point at an opposite edge of the bigFET gate finger manifold.

3. The method of claim 2, further comprising:
using a first set of P-type Metal-Oxide-Semiconductor (PMOS) pre-drivers to send a first triggering signal to a first portion of an array of Metal-Oxide-Semiconductor Field-Effect Transistors (MOSFETs) via the first feeding point; and
using a second portion of PMOS pre-drivers to send a second triggering signal to a second portion of the array of MOSFETs via the second feeding point.

4. The method of claim 3, wherein the use of the first feeding point and the second feeding point shifts a higher net resistance to a central portion of the bigFET gate finger manifold.

5. The method of claim 1, wherein each of the bigFET gate fingers is connected to both sides of the bigFET gate finger manifold.

6. The method of claim 1, wherein the activated bigFET is implemented by an array of parallel-connected Metal-Oxide-Semiconductor Field-Effect Transistors (MOSFETs) that are arranged in rows and columns.

7. The method of claim 6, wherein the bigFET gate finger manifold interconnects the bigFET gate fingers from the rows and columns of the parallel-connected MOSFETs.

8. The method of claim 1, further comprising:
detecting the ESD event using a resistor-capacitor (RC) circuit;
sending an ESD detection signal to the pre-driver; and
conditioning, by the pre-driver, of the ESD detection signal to generate the triggering signals.

9. The method of claim 8, wherein the conditioning of the ESD detection signal includes amplifying the ESD detection signal.

10. An electrostatic discharge (ESD) power clamp, comprising:
a slew rate detector that generates an ESD detection signal in response to a detected ESD event;
a pre-driver configured to receive and condition the ESD detection signal to generate a plurality of triggering signals; and
a big-Field-Effect Transistor (bigFET) having a plurality of gate fingers that are connected by a gate finger manifold,
wherein the generated triggering signals are fed to different feeding points on the gate finger manifold to activate the bigFET as an ESD power clamp.

11. The ESD power clamp of claim 10, wherein the different feeding points include a first feeding point at one edge of the gate finger manifold and a second feeding point at an opposite edge of the gate finger manifold.

12. The ESD power clamp of claim 11, wherein the pre-driver is further configured to:
use a first portion of P-type Metal-Oxide-Semiconductor (PMOS) pre-driver to send a first triggering signal to a first portion of an array of Metal-Oxide-Semiconductor Field-Effect Transistors (MOSFETs) via the first feeding point; and
using a second portion of PMOS pre-driver to send a second triggering signal to a second portion of the array of MOSFETs via the second feeding point.

13. The ESD power clamp of claim 10, wherein the pre-driver is further configured to amplify the ESD detection signal to generate the plurality of triggering signals.

14. The ESD power clamp of claim 10, wherein the bigFET further comprises an array of Metal-Oxide-Semiconductor Field-Effect Transistors (MOSFETs) having multiple gate fingers to receive the triggering signals.

15. The ESD power clamp of claim 9, further comprising:
a power supply rail (Vdd) and a lower-voltage rail (Vss) for biasing the bigFET,
wherein the activated bigFET shunts ESD current from the Vdd to a Vss.

16. An apparatus, comprising:
a slew rate detector that detects an electrostatic discharge (ESD) event and in response to the detected ESD event, generates an ESD detection signal;
a pre-driver having a physical layout that is split into pre-driver portions to condition the ESD detection signal, wherein the pre-driver portions send triggering signals to a plurality of big-Field-Effect Transistor (bigFET) gate fingers via different feeding points on a gate finger manifold that interconnects in parallel the bigFET gate fingers; and
a bigFET having the plurality of bigFET gate fingers that are connected in parallel by the gate finger manifold, wherein the triggering signals activate the bigFET to shunt an ESD current.

17. The apparatus of claim 16, wherein the different feeding points include a first feeding point at one end and a second feeding point at an opposite end of the gate finger manifold.

18. The apparatus of claim 17, wherein the pre-driver portions include:
a first set of N-channel Metal-Oxide-Semiconductor (NMOS) pre-drivers to send a first triggering signal to a first portion of an array of Metal-Oxide-Semiconductor Field-Effect Transistors (MOSFETs) via the first feeding point; and
a second set of NMOS pre-drivers to send a second triggering signal to a second portion of the array of MOSFETs via the second feeding point.

19. The apparatus of claim 18, wherein the use of the first feeding point and the second feeding point shifts a higher net resistance to a central portion of the gate finger manifold.

20. The apparatus of claim 16, further comprising:
a resistor-capacitor (RC) circuit to detect the ESD event.
